(19) United States
(12) Patent Application Publication
(10) Pub. No.: US 2012/0200308 A1
(43) Pub. Date: Aug. 9, 2012

(54) SUPERCAPACITOR ELECTRODES

(75) Inventor: Scott W. Donne, Callaghan (AU)

(73) Assignee: NEWCASTLE INNOVATION LIMITED, Callaghan, New South Wales (AU)

(21) Appl. No.: 13/499,910

(22) PCT Filed: Sep. 30, 2010
(86) PCT No.: PCT/AU2010/001288

§ 371 Date: Apr. 2, 2012

(30) Foreign Application Priority Data
Oct. 2, 2009 (AU) 2009904798

(51) Int. Cl. G01R 27/26; C25D 7/00; C25D 21/18; C25D 21/12; C25D 9/04; C25D 5/54

(52) U.S. Cl. 324/686; 205/333; 205/162; 205/99; 205/83; 205/50

(57) ABSTRACT

The present invention relates to a method of producing an electrodeposited metal oxide coating for a supercapacitor electrode. The present invention relates to the chronoamperometric electrodeposition of the metal oxide over a period from a few seconds, up to about 30 seconds leading to superior performance as a result of an increased surface area of the deposit. According to the present invention, the capacitances achieved are typically greater than 1300 F/g, and in some instances, over 4000 F/g.

### CROSS-REFERENCE TO RELATED APPLICATIONS

The present disclosure is entitled to the benefit under 35 U.S.C. §120 of International Patent Application PCT/AU2010/001288, filed: 30 Sep. 2010, entitled: Supercapacitor Electrodes,” which claims the benefit of priority to Australian Patent Application Serial No. AU 2009904798, filed 2 Oct. 2009, which claims the benefit of priority to Australian Patent Application Serial No. AU 2008905006, filed 25 Sep. 2008, the disclosures of which are hereby incorporated herein by reference in their entirety for all purposes.

### FIELD OF THE INVENTION

The present invention relates to supercapacitor electrodes and in particular, to manganese oxide-based supercapacitor electrodes wherein the oxide is coated upon the electrode by chronoamperometric electrodeposition. Although the invention will be described hereinafter with particular reference such applications, it will be appreciated that it is not limited to this particular field of use.

### BACKGROUND OF THE INVENTION

Any discussion of the prior art throughout the specification should in no way be considered as an admission that such prior art is widely known or forms part of common general knowledge in the field.

One of the greatest challenges faced by modern society is the efficient supply of energy. Currently, the majority of energy is produced in fossil fuel-burning power stations, which are major contributors to environmental greenhouse gas emissions. Recently, considerable effort has been expended in the development and expansion of “renewable” energy, such as hydroelectric, solar, geothermal, wind, biomass, etc. However, at present, none of these new technologies has the realistic ability to substitute economically for fossil fuel-based power [N. S. Lewis, Scientific Challenges in Sustainable Energy Technology, Plenary Lecture 208^{th} Meeting of the Electrochemical Society, Los Angeles, October 2005]. Therefore, it is likely that future energy production will be more distributed and intermittent, in order to capitalise on these smaller-scale, “renewable” forms of energy.

One of the principal drivers in escalating energy demands is the ever-increasing array of electronic products such as computers, communication devices, and programmable consumer electronics. In order to improve the performance of these and other electronic products, the capacitors used in such products must have ever-greater capacity and ever-higher stability. With the consumer products revolution comes an increased awareness of the importance of energy storage and energy efficiency. Various energy storage options exist, particularly when stored as chemical energy, in which case batteries, capacitors (including supercapacitors) and fuel cells are the alternatives.

The relative characteristics of batteries, supercapacitors and fuel cells have been summarised by Ragone [D. Ragone, Proc. Soc. Automotive Engineers Conference, Detroit, May 1968]. In summary, fuel cells provide the highest energy density at the expense of power density, whilst the performance of supercapacitors is essentially the opposite. Batteries generally occupy a region intermediate fuel cells and supercapacitors, providing greater energy density than supercapacitors and greater power density than fuel cells. Extensive global research has been devoted to optimising the performance of each power source, as well as identifying their preferred applications. The focus of such research is broadly categorised as being either advanced material development (such as in the case of the present invention), or system development through the construction of more efficient, higher performance devices.

In a conventional capacitor, energy is stored by the removal of charge carriers, typically electrons, from one metal plate and depositing them upon another. This charge separation creates a potential difference between the two plates, which can be harnessed in an external circuit. The total energy stored in this fashion is proportional both to the number of charges stored and the potential between the plates. The number of charges stored is essentially a function of size and the material properties of the plates, whilst the potential between the plates is limited by the dielectric breakdown; different spacer materials between the plates result in different voltages. Optimising the spacer leads to higher energy densities for any given size of capacitor.

One form of supercapacitor can be broadly classified as an electric double layer capacitor (EDLC) which employs particles or fibers having a high specific surface area as an electrode material. Other forms of supercapacitor comprise a metal oxide or a conductive polymer.

An EDLC has a relatively long lifespan, but due to the accumulation of charges only at the surface of the electric double layer, the capacitance of an EDLC is generally lower than that of a metal oxide-based or an electrically-conductive polymer-based supercapacitor. The metal of a metal oxide-based supercapacitor is capable of undergoing a change in its multiple valence states, which allows fast reduction and fast oxidation reactions to take place. The redox reactions, corresponding to respective discharging and charging processes, require the ion and electron to move rapidly between the electrolyte and the electrode. Accordingly, the electrode is preferred to have a high specific surface area, and the electrode-active material ideally has a high electrical conductivity.

The present invention relates to ongoing attempts in the art to increase or optimise supercapacitor energy density, thereby making supercapacitors more broadly applicable as power sources. Commercially-available supercapacitors are symmetrical devices (identical electrodes) employing activated carbon electrodes with either an aqueous (e.g., H₂SO₄) or non-aqueous (e.g., tetraalkylammonium tetrafluoroborate in acetonitrile) electrolyte [P. Simon and Y. Gogotsi, Nature Materials, 7 (11) (2008) 845]. Whilst the performance of such devices generally shows high power density and long cycle life, their energy density is limited, as mentioned above. A strategy for improving supercapacitor energy density is to incorporate a pseudo-capacitive electrode [B. E. Conway, Electrochemical Supercapacitors: Scientific Fundamentals and Technological Applications, Kluwer-Plenum Publishing Company, New York (1999)]; i.e., an electrode that can store charge in the double layer (i.e., as a conventional supercapacitor electrode would do), as well as undergo fast reversible surface redox reactions. These types of electrodes have an enhanced capacitance compared with carbon-based electrodes as a result of the “faradaic contribution”, as well as a higher density. As a result, their volumetric energy density is also enhanced.

The prototypical supercapacitor electrode material is amorphous hydrated ruthenium dioxide (RuO₂.xH₂O) which has been reported to have a capacitance exceeding 900 F/g in an aqueous H₂SO₄ electrolyte [K. Naoi and P. Simon, Interface, 17 (1) (2008) 34]. However, the commercial scope of RuO₂ is limited primarily by cost. Accordingly, the art has sought suitable alternatives exhibiting similar behaviour.

Alternative systems based on other metal oxides and conductive polymers have been reported in the literature to behave similarly to RuO₂. Of these, metal oxides are preferred because of their higher energy density [see, Conway & Naoi, each above]. Within this category of metal oxides, systems based on manganese dioxide are presently receiving considerable attention from the scientific community [D. Bélanger, T. Brousse and J. W. Long, Interface, 17 (1) (2008) 49]. Manganese dioxide is attractive because it may be formed via numerous synthetic methods resulting in wide-ranging morphologies, coupled with good faradaic electrochemical performance, low cost and relative environmental friendliness [e. g., W. Feitknecht and W. Marti, Helv. Chim. Acta, 28 (1945) 129. W. Feitknecht and W. Marti, Helv. Chim. Acta, 28 (1945) 149. O. Glemser, G. Gattow and H. Meisiek, Z. anorg. allg. Chem., 309 (1961) I. Y. F. Yao and H. S. Wroblowa, J. Electroanal. Chem., 223 (1987) 107. R. M. McKenzie, Miner. Mag., 38 (1971) 493. J. B. Fernandes, B. D. Desai and V. N. Kamat Dalal, J. Power Sources, 15 (1985) 209. E. Narita and T. Okabe, Bull. Chem. Soc., Japan, 53 (1980) 525. M. H. Rossouw, D. C. Liles and M. M. Thackeray, Prog. Batteries and Battery Mater., 15 (1996)].

For instance, U.S. Pat. No. 7,199,997 discloses an asymmetric supercapacitor having as a positive terminal a material selected from manganese dioxide, silver oxide, iron sulfide and mixtures thereof. The negative electrode is a carbonaceous active material. In a preferred embodiment, at least one of the electrodes has nanostructured/nanofibrous material.

Chinese patent number CN 101286418 discloses a manganese dioxide electrochemical supercapacitor. The positive electrode is manganese dioxide material having high capacitance, the negative electrode is a high surface area carbon material, the electrolyte is an aqueous solution containing divalent cations, thus forming the asymmetric electrochemical capacitor. As different materials are adopted in different electrochemical windows of the same electrolyte, the individual voltage of the asymmetric electrochemical capacitor can be up to 2V or more, and as the divalent cations are adopted as cations of the electrolyte, the specific capacity of the positive electrode and the negative electrode are improved.

The present invention pertains to the use of electrodeposited manganese oxides for supercapacitor electrodes. Whilst obtaining manganese oxides via electrodeposition is not new—indeed, commercial production of manganese dioxide is primarily by electrodeposition—the materials produced by existing processes are intended for alkaline battery usage rather than for supercapacitors.

Commercial supercapacitors employ activated carbon electrodes, which typically have a specific capacitance of, at best, around 150 F/g. The best reported capacitance from a manganese dioxide electrode material was previously around 800 F/g. Further, the best reported capacitance from any supercapacitor electrode material to date is that of hydrated ruthenium dioxide (˜1300 F/g).

Generally-speaking, what differentiates the present invention from the prior art is firstly, the duration over which the electrodeposition is carried out. Commercial production of manganese dioxide is generally effected over an approximate three week period. However, in the supercapacitor literature, electrodeposition has been reported over time periods of around one minute or longer. By contrast, the present Applicant has surprisingly shown that the electrodeposition of manganese dioxide over a period from a few seconds, up to about 30 seconds leads to superior performance, possibly as the result of increased surface area of the deposit. Secondly, the electrolytes used by the present Applicant are different to those used in the existing supercapacitor literature. Thirdly, in the present invention, the transition between electrodeposition and testing regime is markedly different in the sense that it does not involve a drying step. This likely has the effect of retaining the pore structure of the electrodeposited manganese dioxide, which if it were dried, would decrease considerably. Finally, the electrodeposition of manganese oxides has the added advantage that it produces an electrode that is already in a suitable state for inclusion into a supercapacitor device.

The Applicant has noted the excellent and surprising performance of electrodeposited thin films of manganese dioxide in aqueous electrolytes. One of the principal advantages of this electrodeposited material is its inherent processing characteristics in that it requires only minimal additional processing by comparison with the alternative powder coating method that requires several processing steps. A further advantage is by way of the capacitance of the materials produced by such a process. Such materials typically display capacitance within the range of about 2000 F/g to about 4000 F/g.

It is an object of the present invention to overcome or ameliorate at least one of the disadvantages of the prior art, or to provide a useful alternative.

It is an object of an especially preferred form of the present invention to provide a means of coating an electrode for a supercapacitor, the coating having a relatively high specific surface area and a relatively good electrical conductivity, the supercapacitor ideally capable of maintaining a relatively high specific capacitance during high-speed charging and discharging cycles.

An added advantage of the present invention is that using the inventive electrodeposition process provides an electrode. Although the preferred substrate for the inventive electrodeposition process is platinum, any other suitable substrate may be employed; particularly suitable candidates include titanium and conductive glasses.

Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”.

Although the invention will be described with reference to specific examples it will be appreciated by those skilled in the art that the invention may be embodied in many other forms.

### SUMMARY OF THE INVENTION

According to a first aspect of the invention there is provided a method for chronoamperometrically electrodepositing a metal oxide upon a working electrode, said method comprising the steps of:
providing within an electrochemical cell a working electrode; a counter electrode; and an electrolytic solution comprising cations of said metal and an acid;
operatively associating said working electrode, said counter electrode and said electrolytic solution within said electrochemical cell;
applying one or more predetermined chronoamperometric step voltages to said electrochemical cell for a predetermined period, thereby to effect electrodeposition of said metal oxide upon said working electrode.
As used in accordance with the present invention, the term “working electrode” is intended to mean the substrate upon which the electrodeposition takes place.
In an embodiment, said metal is selected from the group consisting of transition metals. More preferably, said metal is selected from the group consisting of manganese, titanium and ruthenium. In a preferred embodiment, said metal oxide is manganese dioxide.
In an embodiment, said working electrode is selected from the group consisting of platinum, titanium and conductive glasses. Preferably, said working electrode is a platinum disk working electrode. In an embodiment, said counter electrode is a carbon rod counter electrode.
In an embodiment, said electrolytic solution is a metal cation/acid electrolytic solution. Preferably, said electrolytic solution comprises said metal cation at a concentration of from about 0.001 to about 1.0 M. In an embodiment, said metal cation is Mn²⁺. In an embodiment, said electrolytic solution comprises said acid up to a concentration of about 1.0 M. Preferably, said acid is H₂SO₄. In a preferred embodiment, said electrolytic solution is a MnSO₄/H₂SO₄ solution.
In an embodiment, said method takes place at between about 0° C. to about 40° C. Preferably, said method takes place at substantially ambient temperature.
In an embodiment, said predetermined period is from about 5 to about 60 seconds. Preferably, said predetermined period is about 30 seconds.

In an especially preferred embodiment, the working electrode is platinum, the counter electrode is carbon, the predetermined period is about 30 seconds, the electrolytic solution is 0.001 M MnSO₄/0.1 M H₂SO₄, and applying the one or more predetermined chronoamperometric step voltages to the electrochemical cell results in a thin layer of manganese dioxide being coated upon the surface of the platinum working electrode. The resultant coated electrode was found to have capacitance in the range of about 2000 F/g to about 4000 F/g.
In an embodiment, said electrolytic solution is conditioned prior to said electrodeposition. Preferably, the conditioning of said electrolytic solution is effected by degassing said solution with humid nitrogen gas for around ten minutes.
In an embodiment, said one or more predetermined chronoamperometric step voltages is/are selected from analysis of a linear sweep voltammogram of said working electrode relative to a reference electrode in said electrolytic solution.
In an embodiment, said reference electrode is a saturated calomel (SCE) reference electrode. Preferably, said linear sweep voltammogram of said working electrode in said electrolytic solution is provided from an open circuit voltage up to 1.6 V at 5 mV/s.
In an embodiment, said one or more predetermined chronoamperometric step voltages is/are selected from the non diffusion-limited and the diffusion-limited voltage range.
In an embodiment, said one or more predetermined chronoamperometric step voltages comprise at least one in the non diffusion-limited and at least one in the diffusion-limited voltage range. Preferably, said one or more predetermined chronoamperometric step voltages comprise two in the non diffusion-limited and two in the diffusion-limited voltage range. In an embodiment, said one or more predetermined chronoamperometric step voltages are a function of the electrolytic solution.
In an embodiment, the voltage at which said metal oxide electrodeposition occurs is dependent upon both said cation and said acid concentrations in said electrolytic solution.
In an embodiment, said metal cations are present in a relatively low concentration; said acid is present in a relatively high concentration; and said step voltage is in the non diffusion-limited region. Most preferably, said metal cations are Mn²⁺ at a concentration of about 0.01 M; said acid is H₂SO₄ at a concentration of about 0.1 M; and said step voltage is 1.05 V.
According to a second aspect of the present invention there is provided a working electrode when coated with a metal oxide by a chronoamperometric electrodeposition method defined according to the first aspect of the present invention.
According to a third aspect of the present invention there is provided an electrical device having an energy storage unit comprising an electrode coated with a metal oxide by a chronoamperometric electrodeposition method defined according to the first aspect of the present invention.

According to a fourth aspect of the present invention there is provided an electrode coated with a metal oxide and having a specific capacitance of greater than about 1300 F/g. Preferably, said specific capacitance is between about 2000 F/g and about 4000 F/g.

In an embodiment, said metal oxide is manganese dioxide. In another embodiment, said electrode is platinum, titanium or conductive glass. Preferably, said electrode is platinum.

In an embodiment, said metal oxide is coated upon said electrode to a thickness of about 40 nm. In an embodiment, said metal oxide is relatively porous. Preferably, said metal oxide is coated upon said electrode at a density below about 4.0 g/cm³.
In an embodiment, said metal oxide has a specific surface area (BET) of ≧1000 m²/g. Preferably, said metal oxide has a specific surface area (BET) of about 1300 m²/g.
According to a fifth aspect of the present invention there is provided an electrode for use in a supercapacitor, said electrode being coated with a metal oxide and having a specific capacitance of greater than about 1300 F/g. Preferably, said specific capacitance is between about 2000 F/g and about 4000 F/g.
In an embodiment, said metal oxide is manganese dioxide. In another embodiment, said electrode is platinum, titanium or conductive glass. Preferably, said electrode is platinum.
In an embodiment, said metal oxide is coated upon said electrode to a thickness of about 40 nm. In an embodiment, said metal oxide is relatively porous. Preferably, said metal oxide is coated upon said electrode at a density below about 4.0 g/cm³.
In an embodiment, said metal oxide has a specific surface area (BET) of ≧1000 m²/g. Preferably, said metal oxide has a specific surface area (BET) of about 1300 m²/g.
According to a sixth aspect of the present invention there is provided an electrode coated with a metal oxide and having a specific capacitance of greater than about 1300 F/g, when used in an electrical device. Preferably, said specific capacitance is between about 2000 F/g and about 4000 F/g.
According to a seventh aspect of the present invention there is provided an electrode comprising a substrate and a coating of a transition metal thereupon, said coating having a thickness of about 40 nm and a specific surface area (BET) of ≧1000 m²/g.

In an embodiment, said electrode has a specific surface area (BET) of about 1300 m²/g. In another embodiment, said metal oxide of manganese dioxide.
According to an eighth aspect of the present invention there is provided a method for determining the capacitance of a working electrode when coated with a metal oxide by a chronoamperometric electrodeposition method defined according to the first aspect of the present invention, said method comprising the steps of:
   operatively associating said working electrode with a cycling electrolytic solution;
   equilibrating said working electrode for a second predetermined period; and
   cycling said working electrode for a predetermined number of cycles under open circuit conditions, thereby to provide data from which said capacitance can be calculated.

In an embodiment, said cycling electrolytic solution is within a second electrochemical cell. In an embodiment, said working electrode is cleansed prior to said equilibration step. Preferably, said cleansing comprises a rinsing step and a drying step.

In an embodiment, said second predetermined period is about 1 hour. In another embodiment, said cycling electrolytic solution is nitrogen-purged 0.5 M Na₂SO₄.

In an embodiment, said open circuit conditions comprise cycling in the voltage range of about 0 to about 0.8 V versus a saturated calomel reference electrode at 5 mV/s for at least 50 cycles against a carbon counter electrode. In an embodiment, said data are in the form of a voltammogram.

### BRIEF DESCRIPTION OF THE DRAWINGS

A preferred embodiment of the invention will now be described, by way of example only, with reference to the accompanying drawings in which:

FIG. 1 is a schematic diagram of the electrochemical cell. The working electrode (platinum) is designated “WE”, the counter electrode (carbon) designated “CE”, and the reference electrode (saturated calomel electrode) is designated “RE”. The gas in/gas out ports are for degassing the electrolytic solution with humid nitrogen gas;

FIG. 2 is an example of the linear sweep voltammetry obtained from a sweep of the platinum working electrode in 0.1 M Mn²⁺ (as MnSO₄) with H₂SO₄ concentrations varying from 0.001 to 0.1 M;

FIG. 3 represents the proposed mechanistic pathways (see, Paths A, B and C, below) for the electrodeposition of manganese dioxide according to the present invention. In practice, a combination of all three is likely;

FIG. 4 shows a typical example of the resultant chronoamperometry data, in the case with an electrolyte of 0.1 M Mn²⁺ (as MnSO₄) in 0.001 M H₂SO₄. The steps to 0.95 and 1.05 V were activation-controlled, while the steps to 1.15 and 1.25 V were mass transport-controlled;

FIG. 5 shows an example of the amount of charge passed during chronoamperometric deposition (period=30 seconds). In this case, the electrolyte consisted of varying amounts of Mn²⁺ (0.001-1.0 M, as MnSO₄) with 0.01 M H₂SO₄;

FIG. 6 is a typical voltammogram for an electrodeposited manganese dioxide electrode made in accordance with the present invention;

FIG. 7 depicts a cycle life example (capacitance versus number of cycles) for manganese dioxide electrodeposited upon a platinum electrode in accordance with the present invention;

FIG. 8a shows specific capacitance at the 50^{th} cycle for the electrodeposited manganese dioxide samples as a function of Mn²⁺ concentration (0.001 M);

FIG. 8b shows specific capacitance at the 50^{th} cycle for the electrodeposited manganese dioxide samples as a function of Mn²⁺ concentration (0.01 M);

FIG. 8c shows specific capacitance at the 50^{th} cycle for the electrodeposited manganese dioxide samples as a function of H₂SO₄ concentration (0.1 M);

FIG. 9 demonstrates the effect of deposition temperature on capacitance for a manganese dioxide electrodeposit on a platinum electrode produced in accordance with the present invention;

FIG. 10 shows the effect of deposition time on specific capacitance and confirms that the relatively short deposition period of the present invention provides for relatively optimised capacitance; and

FIG. 11 is a schematic diagram of the manganese discharge mechanism in basic and acidic electrolytes.

### PREFERRED EMBODIMENT OF THE INVENTION

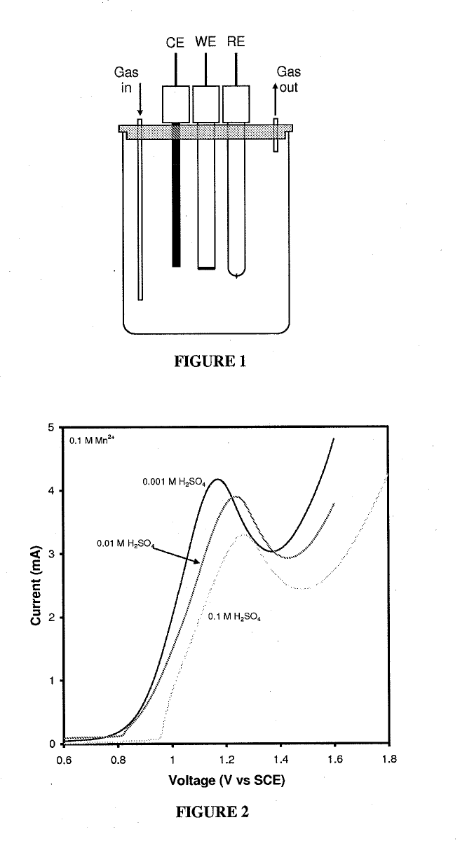

A preferred embodiment of the invention will now be described, by way of example only, with reference to FIG. 1 of the accompanying drawings in which the cell used for electrodeposition consists of a 250 mL glass beaker with a machined PTFE lid. The electrodes are an epoxy body platinum disk working electrode (WE) (1.325 cm²), a carbon rod counter electrode (CE), and a saturated calomel reference electrode (RE) against which all voltages are reported unless otherwise stated. The temperature is ambient (i.e. 22.0±0.5° C.), however, this can be varied between 0.0±0.5° C. using an ice-water bath, or around 40° C. through the use of a thermostat-controlled heating jacket.

The working electrode was firstly cleaned in a bath of acidic hydrogen peroxide (0.1 M H₂SO₄+10% H₂O₂) to remove any residual manganese dioxide present from previous experiments. The platinum was then polished by rubbing on a moist cloth coated with 1 μm alumina particles for about two minutes. The electrode was then rinsed thoroughly with Milli-Q ultra pure water to remove any attached alumina particles before being patted dry with a lint-free tissue. The clean working electrode was then placed in the electrochemical cell together with the counter and reference electrodes, and an electrolytic solution of 0.01 M MnSO₄ and 0.1 M H₂SO₄ that had previously been degassed with humid nitrogen gas for 10 minutes was added such that the electrolytic solution, the WE, CE and RE were each operatively associated within the cell.

To identify suitable chronoamperometric step voltages, a linear sweep voltammogram of the WE in the electrolytic solution was conducted from the open circuit voltage up to 1.6 V at 5 mV/s. The resultant voltammogram was analysed and appropriate step voltages were chosen; two in the non diffusion-limited (i.e. 0.95 and 1.05 V) and two in the diffusion-limited (i.e. 1.15 and 1.25 V) voltage range. The selected chronoamperometric voltages are a function of both the Mn²⁺ and acid concentrations.

Once the step voltages had been determined, the WE was cleaned and then returned to the cell. Chronoamperometry was then conducted by stepping the WE voltage from the open circuit voltage to one of the previously identified step voltages for about 30 seconds to effect electrodeposition of manganese dioxide upon the platinum WE. After this, the WE was removed immediately from the cell, rinsed thoroughly to remove any entrained electrolytic solution with Milli-Q water, and then patted dry with a lint-free tissue.

The coated WE was then immersed directly into a second similar cell containing nitrogen purged 0.5 M Na₂SO₄ and allowed to equilibrate for 1 hour under open circuit conditions. After this time, the manganese dioxide coated WE was cycled in the voltage range 0.0-0.8 V versus the RE at 5 mV/s for at least 50 cycles, again using a carbon CE and an saturated calomel RE.

The resultant manganese dioxide coated WE was found to have an excellent specific capacitance of greater than 1300 F/g and typically within the range of about 2000 F/g to 4000 F/g.

### Experimental

The principal materials used in this work were MnSO₄.H₂O (Sigma Aldrich; >99.5%), concentrated H₂SO₄ (Sigma Aldrich; >98%), and Na₂SO₄ (Sigma-Aldrich; >99%). All solutions from these chemicals were made up using Milli-Q ultra pure water (>18 MΩ resistivity). Manganese dioxide electrodeposition was carried out from a matrix of electrolytes covering the compositional range 0.001-1.0 M Mn²⁺ and 0.0-1.0 M H₂SO₄. To evaluate the performance of the electrodeposited manganese dioxide samples as supercapacitor electrodes, an electrolyte of 0.5 M Na₂SO₄ was used.

A schematic diagram of the cell used for electrodeposition is shown in FIG. 1. It consists of a 250 mL glass beaker with a machined PTFE lid. The electrodes used were an epoxy body platinum disk working electrode (1.325 cm²), a carbon rod counter electrode, and a saturated calomel reference electrode (SCE) against which all voltages are reported unless otherwise stated. Most experiments were conducted at ambient temperature (22.0±0.5° C.). However, a few experiments were conducted at either 0.0±0.5° C. in an ice-water bath, or at elevated temperatures through the use of a thermostat-controlled heating jacket (±1° C.).

Prior to any electrodeposition experiments, the platinum electrode was cleaned chemically in a bath of acidic hydrogen peroxide (0.1 M H₂SO₄+10% H₂O₂) to remove any residual manganese dioxide present from previous experiments. The platinum was then polished mechanically by rubbing on a moist cloth coated with 1 μm alumina particles (2 minutes). After this, the electrode was rinsed thoroughly with Milli-Q ultra pure water to remove any attached alumina particles before being patted dry with a lint-free tissue. The clean platinum electrode was then placed in the electrochemical cell together with the counter and reference electrodes, and the MnSO₄/H₂SO₄ electrolyte that had previously been degassed with humid nitrogen gas for 10 minutes.

The Inventor used chronoamperometry to electrodeposit manganese dioxide upon the substrate. To firstly identify suitable chronoamperometric step voltages, a linear sweep voltammogram of the platinum in the chosen electrolyte was conducted from the open circuit voltage up to 1.6 V at 5 mV/s using a Perkin-Elmer VMP 16-channel potentiostat controlled by Echem software. From this voltammogram, appropriate step voltages were chosen; two in the non diffusion-limited and two in the diffusion-limited voltage range. The voltage at which manganese dioxide electrodeposition occurs is dependent upon both the Mn²⁺ and acid concentrations in the electrolyte, and as such, the chronoamperometric voltages chosen varied depending on the electrolyte. Once the step voltages had been determined, the platinum electrode was cleaned and then returned to the electrodeposition cell. The chronoamperometry experiment was then conducted by stepping the platinum electrode voltage from the OCV to one of the previously-identified step voltages for an appropriate time, typically 30 seconds. After this, the platinum electrode was removed immediately from the electrochemical cell, rinsed thoroughly to remove any entrained electrolyte with Milli-Q water, and then patted dry with a lint-free tissue. It was then immersed directly into a second similar electrochemical cell containing nitrogen purged 0.5 M Na₂SO₄ and allowed to equilibrate for 1 hour under open circuit conditions. After this time, the manganese dioxide electrode was cycled in the voltage range 0.0-0.8 V versus SCE at 5 mV/s for at least 50 cycles, again using a carbon counter electrode and an SCE reference electrode.

A typical example of the measured deposition voltammetric behaviour is provided in FIG. 2. The voltammetric wave observed corresponds to the oxidation of Mn²⁺ to MnO₂ superimposed on oxygen evolution. This was to be expected given the identical E^{o} values for the two redox half-reactions [M. Pourbaix, Atlas of Electrochemical Equilibria in Aqueous Solutions, National Association of Corrosion Engineers, Houston (1974)]; i.e.,

MnO₂+4H⁺+2e⁻ [symbol] Mn²⁺+2H₂O (E^{o}=1.23 V) (1)

O₂+4H⁺+4e⁻ [symbol] 2H₂O (E^{o}=1.23 V) (2)

The E^{o} value for the MnO₂/Mn²⁺ redox couple assumes the thermodynamically stable β-MnO₂ as the manganese dioxide phase produced, although the literature would dictate that metastable γ-MnO₂ was the phase produced under these conditions [C. B. Ward, A. I. Walker and A. R. Taylor, Prog. Batt. Batt. Mater., 11 (1992) 40]. With reference to FIG. 2, a shift in voltage was noted for both redox processes toward more positive values, and also the decrease in peak current, particularly for the MnO₂/Mn²⁺ redox couple. The shift to higher voltages is justified by considering the Nernst equation for each half reaction. However, the decrease in peak current is not so straightforward, and requires consideration of the electrodeposition mechanism for manganese dioxide.

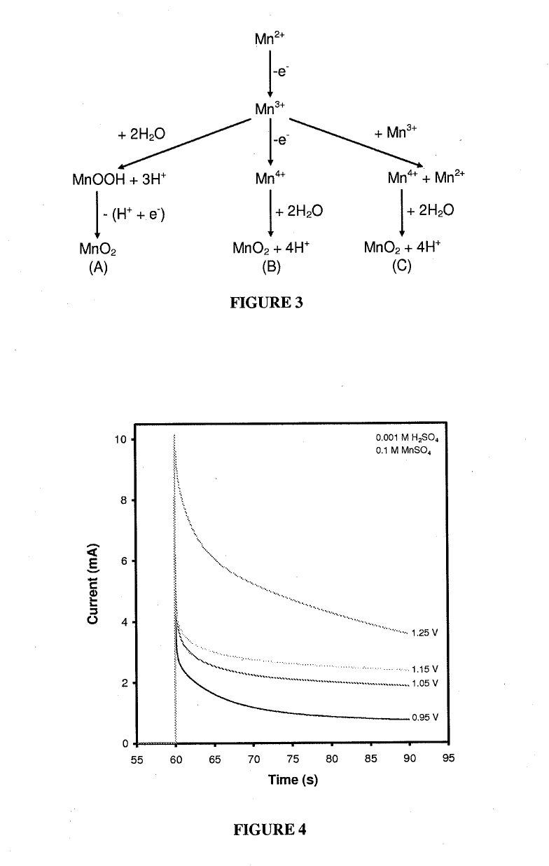

The literature on the electrodeposition of manganese dioxide indicates that there are three potential mechanistic pathways that the process can follow depending upon the experimental conditions employed, i.e., electrolyte composition (Mn²⁺ and H₂SO₄ concentration), temperature and current density; FIG. 3 contains a summary of these pathways. The first step in the electrodeposition process is accepted to be the oxidation of Mn²⁺ to Mn³⁺. Following this, the behaviour of the Mn³⁺ in the electrolyte determines the predominant mechanistic pathway the overall process will take, hereinafter Paths A, B and C.

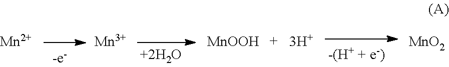

In Path A, the soluble Mn³⁺ is metastable in a non-complexing aqueous media, hydrolysing to form solid MnOOH which precipitates on the electrode surface. The to MnOOH can then undergo topotactic solid-state oxidation to form MnO₂. This mechanism is preferred under conditions where soluble Mn³⁺ is unstable, such as in weakly acidic conditions. Furthermore, the structure of the MnOOH produced is thought to determine the resultant MnO₂ structure.

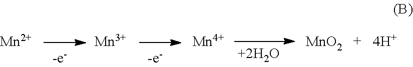

In Path B, the initial Mn²⁺ to Mn³⁺ oxidation process is followed by another one-electron oxidation process to form Mn⁴⁺, which hydrolyses immediately to deposit MnO₂ on the electrode, given that soluble Mn⁴⁺ species in aqueous electrolytes without good complexing ligands have not been reported to exist. The existence of this pathway is questionable given that there is no electrochemical evidence (cf. FIG. 2) to show two sequential redox processes, irrespective of the scan rate employed.

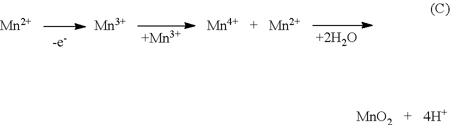

In Path C, the lifetime of the metastable Mn³⁺ produced in the first oxidation step is sufficiently long for it to react with another Mn³⁺ ion and disproportionate to form Mn²⁺ and Mn⁴⁺, the latter of which hydrolyses immediately to deposit MnO₂ on the electrode surface. These electrolyte conditions typically involve higher acid concentration electrolytes.

Despite these well delineated mechanistic pathways, in practice, a combination of Paths A, B and C likely occurs to produce the resultant manganese dioxide. The crystal structure and morphology of the resultant manganese dioxide is a function of the electrolyte conditions and the predominant mechanism.

From the linear sweep voltammetry data for each electrolyte studied (e.g., FIG. 2), four step potentials were chosen; two at voltages below the peak voltage, in which case reaction kinetics are activation-controlled; and two beyond the peak voltage wherein the reaction kinetics are mass transport-controlled (predominantly diffusion, although in some instances migration would contribute). A typical example of the acquired chronoamperometry data is shown in FIG. 4, in this case for 0.1 M Mn²⁺ in 0.001 M H₂SO₄.

To enable comparison between electrodes prepared using different conditions, the mass of manganese dioxide deposited onto the electrode surface must be determined. The most obvious approach is to determine by numerical integration the amount of charge passed during chronoamperometric deposition and then convert that into a mass of manganese dioxide. FIG. 5 contains an example of the theoretical mass of manganese dioxide deposited during chronoamperometric deposition, assuming stoichiometric manganese dioxide is the product. Furthermore, assuming a manganese dioxide density of 4.0 g/cm³ and that a dense deposit is produced, for 0.05 C of charge passed (22.5 μg of MnO₂) the electrode thickness is ˜40 nm. These calculations are to be considered only a rough approximation since there are numerous chemical, electrochemical and morphological features of the electrode that would detract from ideal behaviour.

Firstly, it is a well known fact that most manganese dioxide samples are non-stoichiometric in nature, meaning that there must also be some form of counter-ion present to balance charge in the structure if Mn(IV) is not the only oxidation state present. For example, in Path A, FIG. 3, the Mn(III) species MnOOH is an intermediate in which a proton has been included into the structure to compensate for Mn(III) rather than Mn(IV). In many cases, partial oxidation is possible, particularly for the lower chronoamperometric step voltages, meaning that there could be a sizeable proportion of Mn(III) in the structure. Furthermore, in the electrodeposition electrolytes used by the present Inventor, proton substitution is most likely for charge compensation. Certainly, in electrolytes containing alkali or alkaline earth metal ions, they can be quite readily incorporated into the structure of the host manganese dioxide [V. M. Burns, R. G. Burns and W. K. Zwicker, Proc. MnO₂ Symp., Vol. 1, Eds. A. Kozawa and R. J. Brodd (1975) 288. R. G. Burns and V. M. Burns, Proc. MnO₂ Symp., Vol. 1, Eds. A. Kozawa and R. J. Brodd (1975) 306. R. G. Burns and V. M. Burns, Proc. MnO₂ Symp., Vol. 2, Eds. B. Schumm, H. M. Joseph and A. Kozawa (1980) 97]. The net effect of cationic substitution into the manganese dioxide structure would be to increase the molecular weight and hence, the mass of the deposit. Manganese dioxide is also known to be a relatively hydrated species, with the removal of protons upon heating, for instance, being considered as structural water. Furthermore, the surface of manganese dioxide is also hydrophilic meaning that it will adsorb and hold onto atmospheric water quite effectively. While not directly related to the molecular weight of the deposit, this surface-bound water does contribute mass to to the electrode material.

It has also been demonstrated in FIG. 2, that the electrodeposition of manganese dioxide overlaps with that of oxygen evolution, particularly for the higher step voltages. Therefore, a portion of the charge passed during the chronoamperometry experiment would go to oxygen evolution and hence not contribute to the final mass of the electrode. Under these circumstances the calculated mass would be more than what is actually deposited. Similarly, the prevailing electrodeposition mechanism for manganese dioxide can also have a dramatic impact on the resultant deposit mass. In each of the mechanisms described in FIG. 3, there is a step whereby a soluble intermediate is required to either hydrolyse or disproportionate and hydrolyse to form a species that can precipitate onto the electrode surface. Of course, the location of this hydrolysis or disproportionation process relative to the electrode surface is critical in determining the fraction of manganese that is deposited onto the electrode. If the intermediate is relatively long-lived, it could diffuse or migrate away from the electrode surface before hydrolysing or disproportionating, meaning that it would be effectively lost from the deposit. As such, the charge efficiency would be less than 100%, and the mass deposited less than expected.

Morphologically, it is also unlikely that the manganese dioxide produced forms a dense deposit. Bulk electrodeposited manganese dioxide, as opposed to the thin film produced in accordance with the present invention, can have a BET surface area ranging from 10-100 m²/g, with the majority of this surface being associated with pores, in particular micropores. Furthermore, chemically-precipitated manganese dioxides tend to have an even higher BET surface area. For even the densest form of manganese dioxide (β-MnO₂; 5.1 g/cm³ [G. Aylward and T. Findlay, SI Chemical Data, 6^{th} Edition, John Wiley & Sons (2008)]), produced using thermal methods, its BET surface area is still as high as ˜10 m²/g. Therefore, it is highly likely that the thin films of material produced in accordance with the present invention are quite porous, which leads to a much thicker deposit than what one would otherwise predict. Ultimately, this porosity will be beneficial for supercapacitor performance because it allows for more surface area to be exposed to the electrolyte.

The present Inventor has not attempted to characterise the morphology or crystal structure of any deposit made in accordance with the present invention for the simple reason that when the manganese dioxide-deposited electrode is removed from the plating electrolyte and dried, as is necessary for structural analysis or imaging, the material properties will change, and so structural and morphological measurements made will be a moot point. There is literature available that suggests that when a manganese dioxide sample is prepared and then dried, its morphology changes dramatically, in particular, the characteristic of material porosity, which decreases considerably. Furthermore, something that is relatively unknown is the effect that drying has on the surface chemistry of the manganese dioxide; e.g., surface crystallisation, hydration, reactivity, bond polarity, etc.

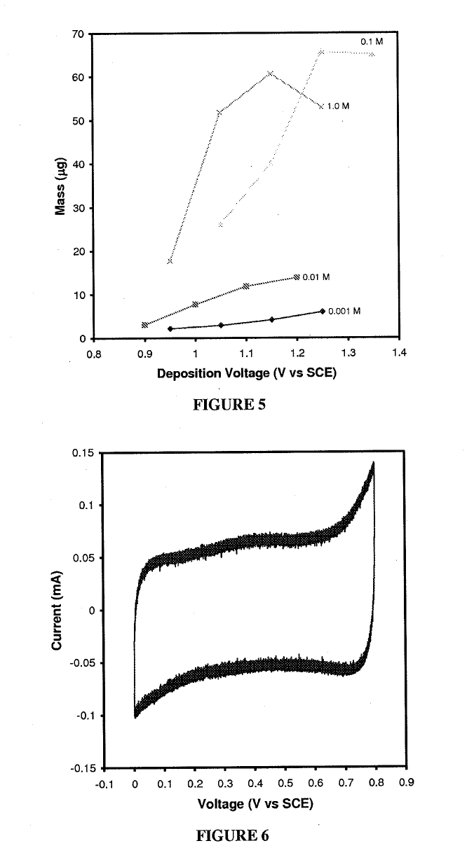

After deposition, the manganese dioxide-coated platinum electrode was removed from the electrolysis bath, washed thoroughly with Milli-Q ultra pure water, patted dry and then transferred immediately to an electrochemical cell containing the cycling electrolyte. After an hour of equilibration, the electrode was cycled potentiodynamically to evaluate its performance. FIG. 6 shows a typical voltammogram obtained from an electrodeposited manganese dioxide electrode; its appearance is as expected for a supercapacitive electrode material. The anodic and cathodic charge passed during each cycle was determined, and then converted to capacitance.

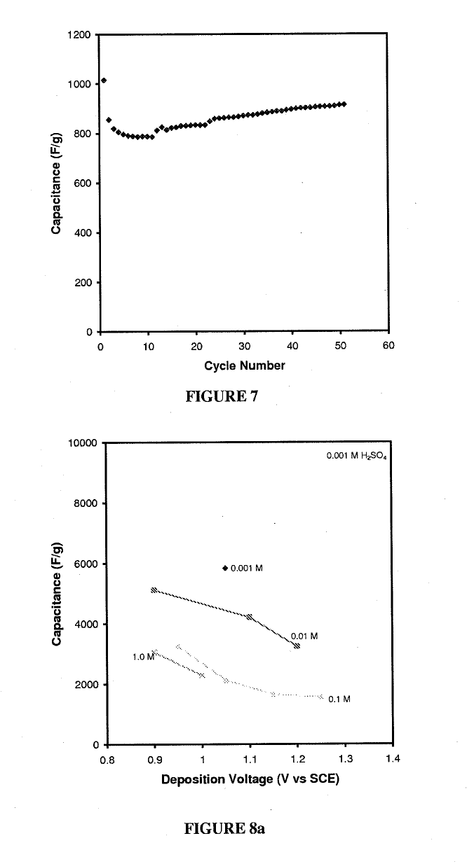

FIG. 7 shows a typical example of how the capacitance varied over the cycle life considered; the capacitance increases slightly with cycling, which is most likely due to the progressive development of the surface exposed to the electrolyte either as a result of increased electrolyte penetration into the pores of the material, or because of some mechanical breakdown of the manganese dioxide as a result of the structural expansion that occurs upon reduction. In the latter case, after cycling was complete, there was no evidence that the deposit had lost adhesion to the platinum substrate. Also immediately apparent in FIG. 7 is the very high specific capacitance for the electrode, calculated assuming that all charge was associated with the electrodeposition of manganese dioxide.

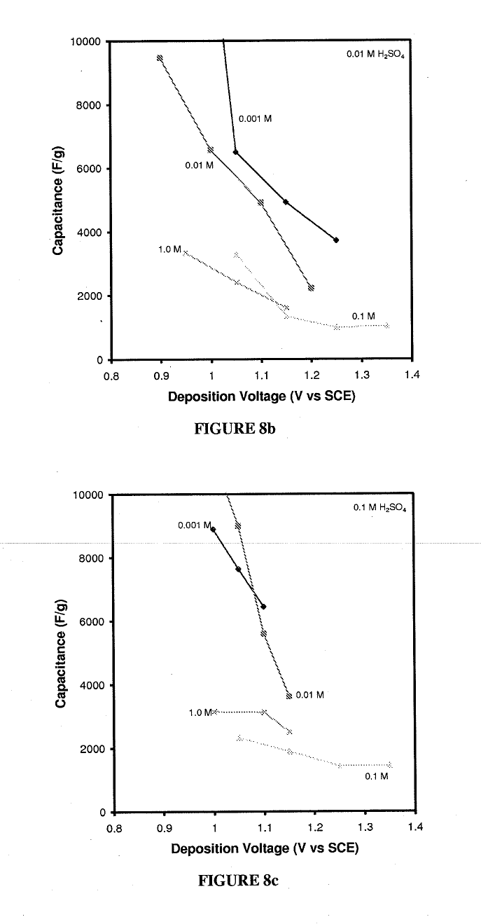

FIG. 8 contains specific capacitance data for all the electrodes prepared. As before, the specific capacitance achieved far exceeds what has been previously reported in the literature [S. C. Pang, M. A. Anderson and T. W. Chapman, J Electrochem. Soc., 147 (2) (2000) 444]. Even within the range of errors that may change the mass from its theoretical value, the capacitances achieved are substantial. Considering the matrix of electrolytes considered, with their corresponding capacitance, one may conclude that under the conditions employed by the present Inventor, the largest capacitance can be extracted when relatively high H₂SO₄ and relatively low Mn²⁺ concentrations are used—and also when the step voltage is in the activation-controlled region, rather than mass transport-controlled.

To explain this behaviour, one must first assume that the specific surface area of the deposit accessible to the electrolyte is proportional to the extracted capacitance. This is a reasonable assumption given that all samples of electrodeposited manganese dioxide came from similar electrolytes, and so the chemistry of these materials is expected to be similar; i.e., there are no different foreign cations to influence the surface chemistry of one sample compared with another; the crystal structure of the material is expected to be similar for the same reasons. Therefore, these electrodeposition conditions are thought to give rise to the highest surface area deposit.

In higher H₂SO₄ concentration electrolytes, the stability of the soluble Mn³⁺ intermediate has been shown to be greater, meaning that its lifetime is longer before either hydrolysis or disproportionation. Another consequence of using a higher H₂SO₄ concentration is that it provides a supporting electrolyte so that mass transport of the Mn²⁺ will be mostly by diffusion, rather than by a combination of diffusion and migration (which would make mass transport faster). Also, the use of a low Mn²⁺ concentration means that mass transport by diffusion to the electrode surface will again be relatively slow. When combined with an activation-controlled deposition voltage, in which case the driving force for mass transport (activity gradient between the bulk electrolyte and the electrode surface) is again not as great, the rate of Mn²⁺ arrival at the electrode surface will again be slow.

In combination, each of the above features of the system indicate that for the best performing electrode, and hence the highest surface area electrode, mass transport of the Mn²⁺ to the electrode surface must be as slow as possible. As a comment on the growth mechanism of the manganese dioxide under these circumstances, it would seem that crystal nucleation predominates so that the maximum surface area can be produced before the pores in the structure fill in to make a denser deposit.

To support these hypotheses, a series of electrodeposition experiments were conducted using an electrolyte of 0.01 M Mn²⁺ in 0.1 M H₂SO₄, an activation-controlled step voltage, at both lower and higher temperatures compared with ambient (i.e., 0° C. and 40° C.). Of course, at lower temperatures the diffusion coefficient for mass transport will be less, and vice versa at high temperatures.

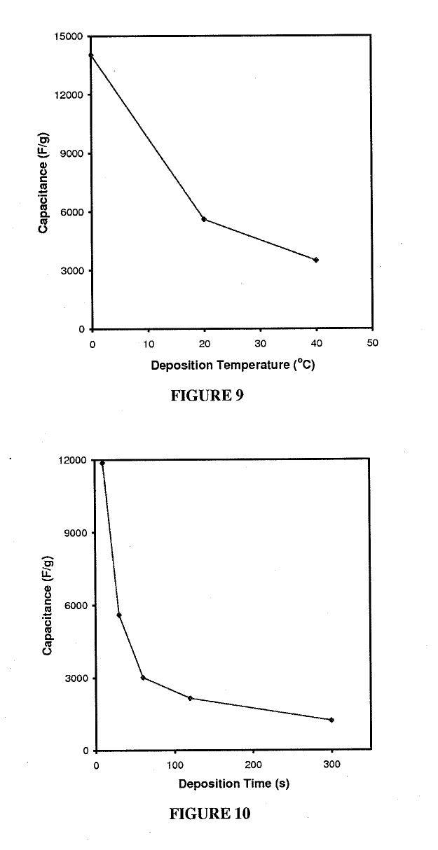

As shown by the capacitance data in FIG. 9, slowing mass transport by lowering the temperature has the effect of increasing the extracted capacitance, thereby supporting the Inventor's theory regarding mass transport and morphology. Additionally, it may also be possible for increased temperature to increase the rate of crystal growth in the deposit as it is being formed. Of course, this will also have the effect of decreasing the available specific surface area and hence, capacitance.

Another set of experiments conducted to explore the mechanism of crystal growth during electrodeposition involved depositing the manganese dioxide for different periods of time, and then measuring the capacitance that can be extracted from the resulting electrode. Again using an electrolyte of 0.01 M Mn²⁺ in 0.1 M H₂SO₄, and an activation-controlled step voltage, electrodeposition of manganese dioxide was carried out for various times ranging from 10 seconds to 5 minutes. The resultant capacitance data are shown in FIG. 10. If the electrodeposition of manganese dioxide continued in the same fashion as the deposition time increased, one should expect a constant specific capacitance. The fact that the capacitance decreases indicates that the available surface area is also decreasing with time. As mentioned above, after an analysis of the effects of the electrodeposition conditions, crystal nucleation apparently predominates during the initial stages of deposition. However, as time passes, rather than continuing to nucleate more crystals and increase the surface area, manganese dioxide is instead deposited in such a fashion as to fill up or close the pores, thus limiting the available surface area. This can be either by crystal growth of the initially-deposited crystals, or by nucleation within the pores.

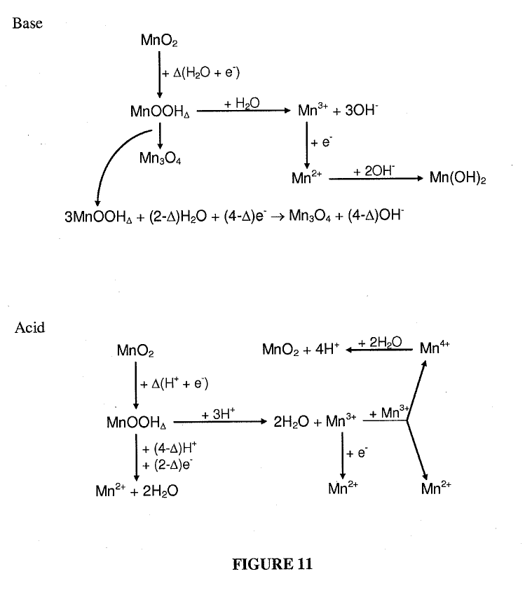

The key feature of a supercapacitive electrode material is its ability to undergo fast reversible surface redox reactions. The redox chemistry of manganese dioxide during electrochemical cycling is very complex, with different reactions apparent when the electrolyte is acidic, basic, or neutral. A schematic outline of these processes is shown in FIG. 11. In a basic electrolyte, the manganese dioxide firstly undergoes proton intercalation. For most phases of manganese dioxide, this is then followed by solubilisation of the resultant Mn(III) species. The exception is the birnessite phase, which as a result of increased lattice strain due to proton intercalation, undergoes structural rearrangement to form electrochemically-inactive Mn₃O₄. The extent to which intercalation occurs (Δ) is dependent upon the manganese dioxide phase and its ability to transport protons through its structure. However, the extent of Mn(III) solubilisation depends on the depth of discharge at the manganese dioxide surface and the base concentration in the electrolyte. For instance, γ-MnO₂ can intercalate and disperse protons quite well throughout its structure, and so Δ→0.9 before solubilisation can occur. However, β-MnO₂ is a poor host for protons, which means that its surface composition approaches MnOOH_{0.9}, but its overall depth of discharge is quite low. In either case, solubilisation in the next step will be enhanced by a more concentrated basic electrolyte (e.g., 7 M), with in fact very little dissolution occurring in electrolytes even as concentrated as 1 M. If the electrode voltage is suitably low, the soluble Mn(III) is then able to be reduced to Mn(II), which precipitates immediately as Mn(OH)₂ throughout the electrode. Even if very little solubilisation occurs, this second electron reduction can occur, albeit to a very small extent on the active material surface because Mn(OH)₂ is essentially an insulator. Solubilisation essentially enhances the dispersion of Mn(OH)₂ throughout the electrode before passivation occurs. Even under ideal circumstances, this second electron reduction is only ˜40% efficient.

There are many similarities between manganese dioxide reduction in basic and acidic electrolytes. The first step is still proton intercalation, which then may be followed by a number of different pathways to form Mn²⁺, which is soluble in the acidic electrolyte. The options include: (i) direct reduction of the solid Mn(III) species; (ii) solubilisation of Mn(III) followed by its reduction to soluble Mn(II); or (iii) disproportionation of soluble Mn(III) to form soluble Mn(II) and insoluble Mn(IV) (as MnO₂). In any case, it is somewhat advantageous that soluble Mn(II) is formed because it avoids passivation of the electrode surface. However, it does release electroactive ions into the electrolyte which can have a significant negative impact.

In neutral electrolytes, the reduction mechanism that manganese dioxide undergoes is most likely an intermediate and somewhat truncated version of the acidic and basic mechanisms, since neither Mn(II) or Mn(III) species have an appreciable solubility under these conditions. Thus, it is reasonable to assume that the manganese dioxide only undergoes a one-electron reduction, which in the bulk involves proton intercalation, and at the surface analogous metal ion (M⁺) association, i.e.,

Bulk+surface: MnO₂+H⁺+e⁻ [symbol] MnOOH (3)

Surface: MnO₂+M⁺+e⁻ [symbol] MnOOM (4)

The evidence in the literature for metals larger than H⁺ and Li⁺ being inserted into the manganese dioxide structure is unconvincing. The theoretical capacitance for this process is 1386 F/g, assuming the starting material is stoichiometric manganese dioxide (this is almost invariably not the case, with the presence of lower-valent manganese ions, cation vacancies and foreign metal ions lowering the stoichiometry) and a voltage window of 0.8 V. Given that the capacitance measured according to the present invention is substantially higher than this, charge must be stored in some other fashion within the electrode. Of course, there is the possibility of charge being stored in the double layer at the manganese dioxide-electrolyte interface, in series with the occurrence of fast redox processes. If this were to be the case, the surface area of the inventive deposit is very high and/or the intrinsic charge storage capacity (F/cm²) is larger than normal.

In terms of surface area, it is highly likely that the manganese dioxide electrodeposited during the course of the above experiments has an large surface area, particularly given the relatively short timeframe over which the deposition was carried out. The evidence for this is apparent in FIG. 10, wherein the capacitance decreases with deposition time due to crystal nucleation within the existing pores effectively closing down the available surface area, as discussed above. If that were the case, then for a specific surface capacitance of say, 15 μF/cm², and a total specific capacitance of 2000 F/g, the surface area is expected to be over 1.3×10⁴ m²/g. Specific surface areas for manganese dioxide have never been reported as being this high, and so while the inventive electrodeposited material may very well have a higher surface area, it is not realistic to assume it is this high. The value used for the surface specific capacitance in the preceding calculation is typical for many metal (and carbon) electrode-electrolyte systems. However, it may not be appropriate for metal oxide systems, in which case the structure and polarity of the oxide groups at the surface is expected to be significantly different. To demonstrate this, one must consider that the “typical” specific capacitance values reported in the literature for manganese dioxide is ˜180 F/g for a material with a specific surface area (BET) of ˜120 m²/g. This equates to a specific surface capacitance of 150 μF/cm², which is an order of magnitude higher than that assumed for a metal electrode. Assuming this value and revisiting the previous calculation, the specific surface area turns out to be ˜1300 m²/g, which, although somewhat high, is not unreasonable.

The source of this enhanced specific capacitance may relate to the fact that the present Inventor has previously shown that the surface of manganese dioxide in an aqueous environment consists of a relatively high concentration of surface hydroxyl groups that exhibit amphoteric behaviour, i.e.,

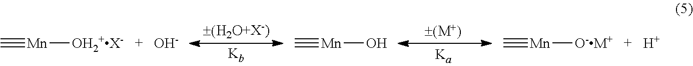

where Kₐ and K_{b} are the acidic and basic equilibrium constants; and X⁻ and M⁺ are generic anionic and cationic counter charges. Whether the surface behaves in an acid or basic fashion is determined by the underlying crystal structure of the manganese dioxide, while the specific sites function depending on Kₐ and K_{b}, and the pH of the electrolyte in which the manganese dioxide is immersed, in which case the hydroxyl groups either release or abstract a proton to or from the electrolyte, respectively. It is apparent that these surface hydroxyl groups are charge storage sites, and instead of using the solution pH as a means to activate or deactivate the surface, the electrode potential can be used instead. For instance, if the electrode potential were made more negative (cathodic), the surface hydroxyl groups on the manganese dioxide can be polarised so that they can abstract a proton or metal ion from the electrolyte as a means of charge balance. This process is of course dependent on the conductivity of the manganese dioxide since the charge applied to the electrode has to find its way to the manganese dioxide-electrolyte interface without incurring significant ohmic polarisation. Furthermore, the conductivity of manganese dioxide (γ-MnO₂) has been reported to decrease substantially (around five orders of magnitude), at least in bulk form, when reduced. Nevertheless, based on the fact that the present invention uses nanoscale deposits, in which case the conduction path lengths are much shorter than in the bulk, material conductivity may not be an issue. Given the voltammogram of FIG. 6, which is typical for an ideal supercapacitor electrode, low conductivity or conductivity changes are apparently not significant.

To estimate the specific surface charge using this model, one must refer back to the crystal structure of the manganese dioxide. To begin, consider the surface area of one formula unit (A_{f}; m²) in the structure; i.e.,

$${A}_{f} = \frac{2 ( {a}_{0} {b}_{0} + {a}_{0} {c}_{0} + {b}_{0} {c}_{0} )}{N} \qquad ( 6 )$$

wherein a₀, b₀ and c₀ are the orthorhombic unit cell dimensions of γ-MnO₂ (9.32 Å, 4.46 Å and 2.85 Å, respectively, and N is the number of formula units per unit cell (N=4 for γ-MnO₂ [V. M. Burns, R. G. Burns and W. K. Zwicker, Proc. MnO₂ Symp., Vol. 1, Eds. A. Kozawa and R. J. Brodd (1975) 288. R. G. Burns and V. M. Burns, Proc. MnO₂ Symp., Vol. 1, Eds. A. Kozawa and R. J. Brodd (1975) 306. R. G. Burns and V. M. Burns, Proc. MnO₂ Symp., Vol. 2, Eds. B. Schumm, H. M. Joseph and A. Kozawa (1980) 97]). Now, assuming stoichiometric MnO₂, this area is therefore associated with two oxygen ions in total, both of which are assumed to be associated with the formation of surface hydroxyl groups, thus giving the surface area per oxygen ion (A_{O}; m²); i.e.,

$${A}_{O} = \frac{{A}_{f}}{2} \qquad ( 7 )$$

Now, the surface capacity (Q_{OH}; C/m²) can be calculated using:

$${Q}_{OH} = \frac{{q}_{O}}{{A}_{O}} \qquad ( 8 )$$

where q_{O} is the charge on an oxygen ion at the surface. If one assumes that q_{O} is the same as the electron charge (qₑ=1.6×10⁻¹⁹ C), then the total capacitance associated with the manganese dioxide surface is given by

$${C}_{T} = \frac{{Q}_{OH}}{V} \qquad ( 9 )$$

wherein V is the voltage window (assumed to be 0.8 V). Under these circumstances, C_{T} calculates to be ˜100 μF/cm², which clearly shows the potential that surface to hydroxyl groups can contribute to the overall capacitance. However, it should be noted that this calculation assumes that each individual unit cell is exposed to the electrolyte, which is of course not possible. Assuming a cluster of unit cells to produce a regular 10 nm×10 nm×10 nm crystal (˜800 unit cells, ˜3200 formula units), the available area will decrease by ˜20 times, meaning the surface capacitance will drop to ˜5 μF/cm². Of course, if the crystal produced is a needle or lathe, then this will influence the unit cell faces exposed to the electrolyte and hence also the hydroxyl group surface density.

One should further note the assumption that all oxide anions are able to form hydroxyl groups. This is perhaps reasonable given the ability of manganese to form an aquo-complex in solution, and also the intrinsic polarisation of the Mn^{δ+}—O^{δ-} bond. It is further noted that this bond polarity will also influence the assumption that a surface oxide ion can be fully associated with the electronic charge; i.e., the bond between manganese and oxygen is assumed to essentially be ionic in nature, which is certainly not the case. The covalency of the bond between manganese and oxygen will act to decrease the total charge available to each oxygen ion (q_{O}), and hence the total capacitance (C_{T}). At this time an estimate for this effect is unavailable.

It will be appreciated by persons skilled in the art that numerous variations and/or modifications may be made to the invention as shown in the specific embodiments without departing from the spirit or scope of the invention as broadly described. Although the invention has been described with reference to specific examples it will be appreciated by those skilled in the art that the invention may be embodied in many other forms.

Those skilled in the art will appreciate that certain terms are used interchangeably throughout the specification and claims, for instance, “electrolyte” and “electrolytic solution” are intended synonymous. Further, one skilled in the art to would understand the “diffusion-limited voltage range” to be synonymous with the “mass transport-controlled voltage range”; and the “non diffusion-limited voltage range” to be equivalent to the “activation-controlled voltage range”.

1.-72. (canceled)

73. A method for chronoamperometrically electrodepositing a metal oxide upon a working electrode, said method comprising the steps of:
providing within an electrochemical cell a working electrode; a counter electrode;
and an electrolytic solution comprising cations of said metal and an acid;
associating said working electrode operatively, said counter electrode and said electrolytic solution within said electrochemical cell;
applying one or more predetermined chronoamperometric step voltages to said electrochemical cell for a predetermined period, thereby to effect electrodeposition of said metal oxide upon said working electrode.

74. A method according to claim 1, wherein said metal is selected from the group consisting of transition metals.

75. A method according to claim 1, wherein said metal oxide is manganese dioxide.

76. A method according to any one of the preceding claims, wherein said working electrode is selected from the group consisting of platinum, titanium and conductive glasses.

77. A method according to claim 1, wherein said electrolytic solution is a metal cation/acid electrolytic solution comprising Mn²⁺ at a concentration of from about 0.001 to about 1.0 M and H₂SO₄ up to a concentration of about 1.0 M.

78. A method according to claim 1, wherein said method takes place at between about 0° C. to about 40° C.

79. A method according to claim 1, wherein said predetermined period is from about 5 to about 60 seconds.

80. A method according to claim 1, wherein said electrolytic solution is conditioned by degassing said solution with humid nitrogen gas for around ten minutes prior to said electrodeposition.

81. A method according to claim 1, wherein said one or more predetermined chronoamperometric step voltages is/are selected from analysis of a linear sweep voltammogram of said working electrode relative to a saturated calomel (SCE) reference electrode in said electrolytic solution.

82. A method according to claim 9, wherein said linear sweep voltammogram of said working electrode in said electrolytic solution is provided from an open circuit voltage up to 1.6 V at 5 mV/s.

83. A method according to claim 1, wherein said one or more predetermined chronoamperometric step voltages is/are selected from the non-diffusion-limited and the diffusion-limited voltage range.

84. A method according to claim 1, wherein said metal cations are Mn²⁺ at a concentration of about 0.01 M; said acid is H₂SO₄ at a concentration of about 0.1 M; and said step voltage is 1.05 V.

85. An electrode coated with a metal oxide and having a specific capacitance of greater than about 1300 F/g, when used in an electrical device.

86. An electrode according to claim 13, wherein said specific capacitance is between about 2000 F/g and about 4000 F/g.

87. A method for determining the capacitance of a working electrode when coated with a metal oxide by a chronoamperometric electrodeposition method defined according to claim 1, said method comprising the steps of:
operatively associating said working electrode with a cycling electrolytic solution;
equilibrating said working electrode for a second predetermined period; and
cycling said working electrode for a predetermined number of cycles under open circuit conditions, thereby to provide data from which said capacitance can be calculated.

88. A method for determining the capacitance A method according to claim 15, wherein said cycling electrolytic solution is nitrogen-purged 0.5 M Na₂SO₄ within a second electrochemical cell.

89. A method according to claim 15, wherein said working electrode is cleansed prior to said equilibration step.

90. A method according to claim 15, wherein said second predetermined period is about 1 hour.

91. A method according to claim 15, wherein said open circuit conditions comprise cycling in the voltage range of about 0 to about 0.8 V versus a saturated calomel reference electrode at 5 mV/s for at least 50 cycles against a carbon counter electrode.
